(19) United States
(12) Patent Application Publication
(10) Pub. No.: US 2025/0210491 A1
(43) Pub. Date: Jun. 26, 2025

(54) VERTICALLY EMBEDDED UTILITY PATCH FOR SEMICONDUCTOR PACKAGES

(71) Applicant: Intel Corporation, Santa Clara, CA (US)

(72) Inventors: Mohamed R. Saber, College Station, TX (US); Shuren Qu, Gilbert, AZ (US); Wei-Lun Jen, Phoenix, AZ (US); Naiya Soetan-Dodd, Mesa, AZ (US); Sheng Li, Gilbert, AZ (US)

(73) Assignee: Intel Corporation, Santa Clara, CA (US)

(21) Appl. No.: 18/396,276

(22) Filed: Dec. 26, 2023

(51) Int. Cl. H01L 23/498; H01L 21/48; H01L 23/13; H01L 23/58; H01L 25/16

(52) U.S. Cl. CPC H01L 23/49833; H01L 21/486; H01L 23/13; H01L 23/58; H01L 25/16

(57) ABSTRACT

Integrated circuit (IC) devices and systems with embedded utility patches, and methods of forming the same, are disclosed herein. In one embodiment, a microelectronic assembly includes a first substrate with a cavity, and one or more second substrates embedded in the cavity. The first substrate is oriented on a first plane, and the one or more second substrates are oriented on one or more second planes that are substantially orthogonal to the first plane.

### BACKGROUND

Current power delivery and routing technologies for semiconductor packages have various limitations. For example, some power delivery technologies have low efficiency, which makes them unsuitable for applications such as integrated power. Moreover, power delivery technologies with high efficiency have other limitations, such as high transient times and challenging fabrication processes. Further, current routing technologies have relatively large size requirements, which makes it challenging to scale down the size of the package.

### BRIEF DESCRIPTION OF THE DRAWINGS

FIG. 1 illustrates an example process flow for forming an integrated circuit (IC) package with an embedded utility patch.

FIGS. 2A-E illustrate another example process flow for forming an IC package with an embedded utility patch.

FIGS. 3A-E illustrate an example process flow for forming an inductor patch.

FIGS. 4A-D illustrate an example process flow for forming a capacitor patch.

FIGS. 5A-D illustrate an example process flow for forming a cable patch.

FIGS. 6A-D illustrate an example process flow for forming an IC package with a heterogenous utility patch.

FIGS. 7A-G illustrate an example process flow for forming an IC package with a cable patch.

FIG. 8 is a top view of a wafer and dies that may be included in a microelectronic assembly.

FIG. 9 is a cross-sectional side view of an integrated circuit device that may be included in a microelectronic assembly.

FIG. 10 is a cross-sectional side view of an integrated circuit device assembly that may include a microelectronic assembly.

FIG. 11 is a block diagram of an example electrical device that may include a microelectronic assembly.

### DETAILED DESCRIPTION

Current power delivery and routing technologies for semiconductor packages have various limitations. For example, some power delivery technologies have low power efficiency, which makes them unsuitable for applications such as integrated power. Moreover, power delivery technologies with high efficiency have other limitations, such as high transient times and challenging fabrication processes. Further, current routing technologies have relatively large size requirements for through holes, which makes it challenging to continue scaling down chip size.

For example, while Coax MIL (CMIL) technology (e.g., coaxial magnetic composite core inductors) provides good value in terms of cost and transient time, it has low power efficiency. Achieving higher power efficiency for CMIL requires the use of high-magnetic-permeability (u) fillers, which are typically alloy-based materials that can leach into wet chemistries used to form copper structures absent proper protection. For example, the power efficiency for CMIL can be increased by passivating the surface of the magnetic paste with a protective electroless (eless) layer, such as a nickel passivation layer. However, the magnetic paste often cracks after plugging and the passivation layer does not fully cover the surface of the magnetic material, which results in a leaching risk.

Enabling integrated power options on semiconductor packages requires architectures with more efficient options for power delivery, such as embedded power delivery components (e.g., magnetic inductor arrays (MIAs), deep trench capacitors (DTCs)). However, while embedded power delivery components provide much better efficiency, they suffer from various challenges, including high transient times and defects from the embedding process (e.g., thickness mismatch, component shifting, etc.). For example, the thickness mismatch between the embedded components and the thicker substrate cores in which they are typically embedded—along with the CTE mismatch between the core and the material surrounding the embedded components—may lead to several issues, such as cavity filling difficulty (e.g., voids), component shift, bleeding issues, and so forth.

Further, the design rules for current routing technologies require plated through holes (PTH) with relatively large width (e.g., 150 μm) and pitch (e.g., 325 μm), which translates to lower density (e.g., 10.9 PTH/mm²), larger footprint/chip size, higher copper migration (e.g., 5-70 μm), and higher loss due to core material and larger PTH inner/outer surfaces, while also making high aspect ratios impossible.

Accordingly, this disclosure presents embodiments of integrated circuits (ICs) with a customizable embedded utility patch, along with methods of forming the same, which can be used for power delivery and through-core routing with higher routing density. In some embodiments, for example, the utility patch may include one or more laminated patch substrates with inductor structures, capacitor structures, and/or routing traces, which may be fabricated horizontally on the respective patch substrates. However, the utility patch may be rotated vertically and then embedded in a package substrate, thus forming vertical inductor and capacitor structures, along with high-density plated through holes (PTHs) with no limit on aspect ratio, which can be used for power delivery and through-core routing on the package substrate (with higher routing density). For example, when the utility patch is embedded vertically in a cavity of a package substrate, the horizontal inductor and capacitor structures become vertical inductor and capacitor structures that extend vertically through the package substrate, and the horizontal routing traces become vertical traces that effectively function as plated through holes (PTHs) extending vertically through the package substrate.

The described embodiments provide various advantages, including high customizability, improved power delivery performance (e.g., high power efficiency, low transient times), smaller footprint, and low cost. For example, the utility patch is highly customizable and can incorporate any number of patches with a variety of features, including through-core patterning and power delivery components (e.g., inductors, capacitors). The utility patch also supports high routing densities, customized capacitance/inductance values, customized thickness/materials for core thickness/CTE compatibility (e.g., mitigating thickness/CTE mismatch issues), and so forth. The vertical inductor structures provide higher efficiency and better transient times. Further, the utility patch enables the use of high magnetic permeability alloy-based materials in the inductor components, while avoiding contact between the magnetic paste and copper wet chemistries. The utility patch enables smaller footprints compared to other power delivery technologies (e.g., embedded MIA/DTC components, CMIL). The utility patch also supports higher PTH densities (e.g., 120 PTH/mm²) compared to other technologies, as the PTHs can be as small as the lithography capability allows (e.g., ˜10 μm vertical traces). In addition, the utility patch can include a combination of PTHs with different design rules (e.g., size, pitch, density) for different purposes. The utility patch routing has much lower copper migration (e.g., due to traces perpendicular to glass cloth), lower loss (e.g., due to smaller size), no limits on through-hole aspect ratios without the need for new plating chemistries, and support for through-core routing (e.g., leading to a layer count reduction). Finally, the utility patches, and the packages/substrates they are embedded in, can be fabricated using existing technologies with low costs.

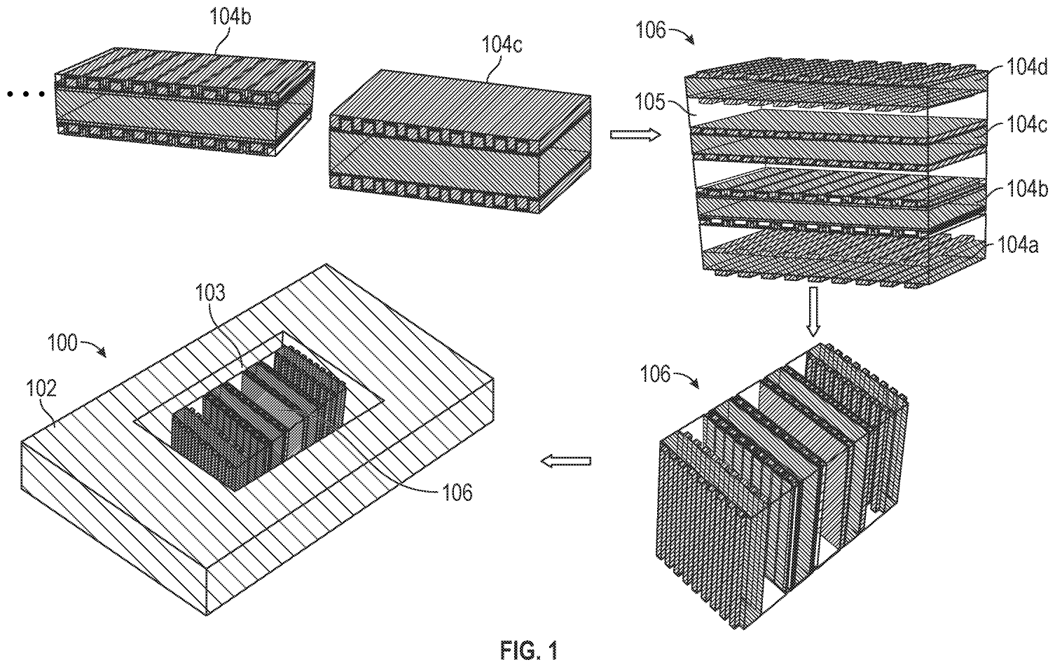

FIG. 1 illustrates an example process flow for forming an integrated circuit (IC) package 100 (e.g., a microelectronic assembly) with an embedded utility patch 106. In the illustrated embodiment, the IC package 100 includes a utility patch 106 with multiple laminated patch substrates 104a-d embedded vertically in a cavity 103 of a package substrate 102, as described below.

The illustrated process flow begins by fabricating or receiving one or more patch substrates 104a-d. Each patch substrate 104a-d may include various features fabricated in a horizontal orientation above and/or below a substrate core, such as one or more inductor structures, capacitor structures, and/or traces.

Next, the respective patch substrates 104a-d are stacked and laminated together with a laminate 105 to form a utility patch 106. In some embodiments, the laminate 105 may be a pre-preg material, which may refer to a composite material with fibers (e.g., glass fibers/fabric) impregnated with a resin.

In the illustrated embodiment, the utility patch 106 includes four patch substrates 104a-d: a cable patch 104a, an inductor patch 104b, a capacitor patch 104c, and another cable patch 104d.

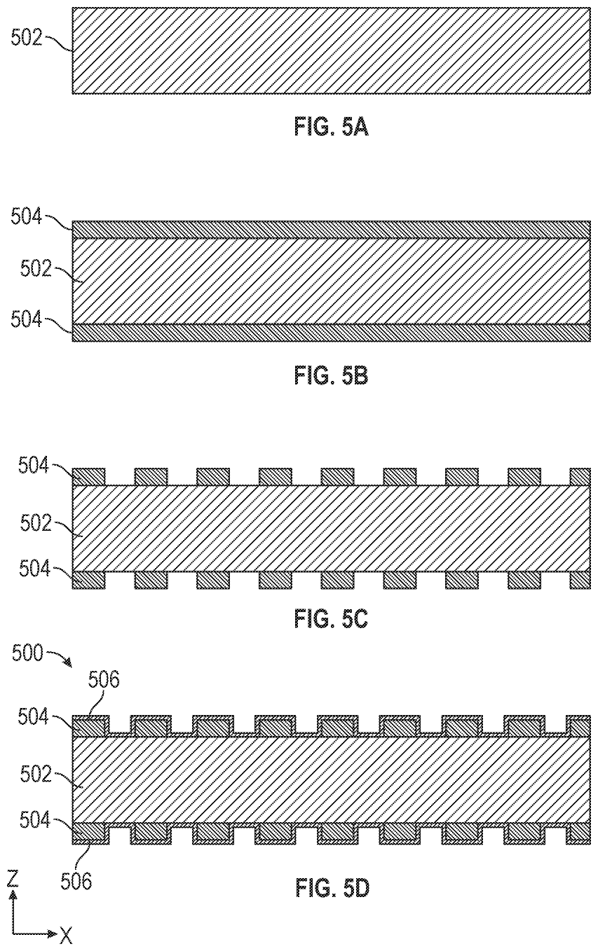

The cable patches 104a,d include conductive traces that are fabricated horizontally on the core of the cable patch substrates 104a,d. When the cable patches 104a,d are subsequently rotated 90 degrees and embedded vertically in the package substrate 102, however, the horizontal traces become vertical traces, which effectively function as plated through holes (PTHs) or vias through the package substrate 102 for vertical routing (e.g., as described further with respective to cable patch 500 of FIGS. 5A-D).

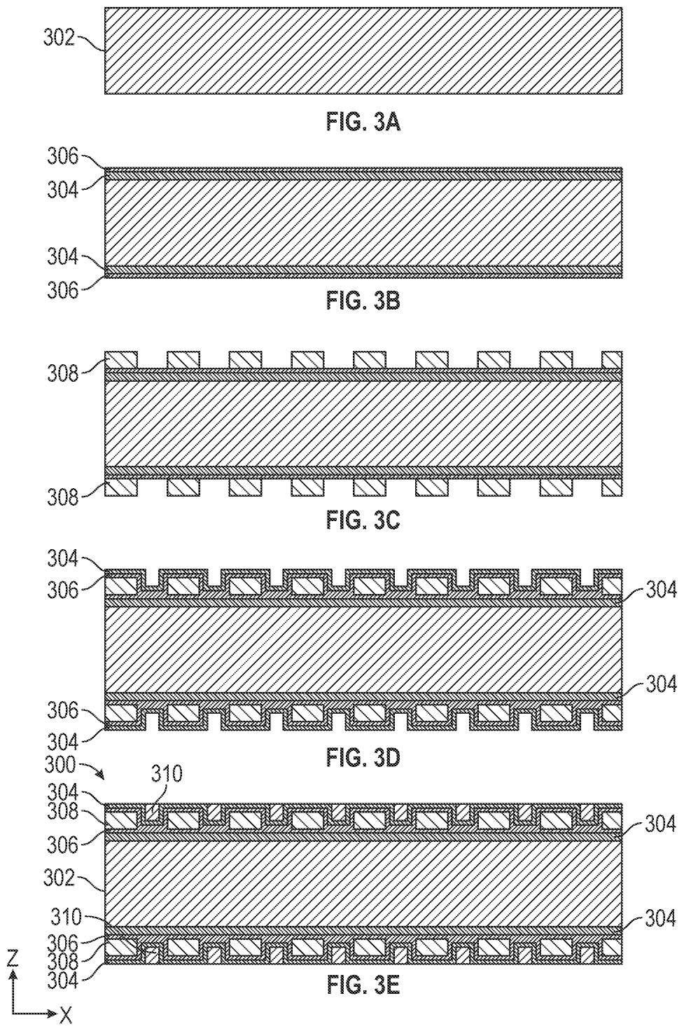

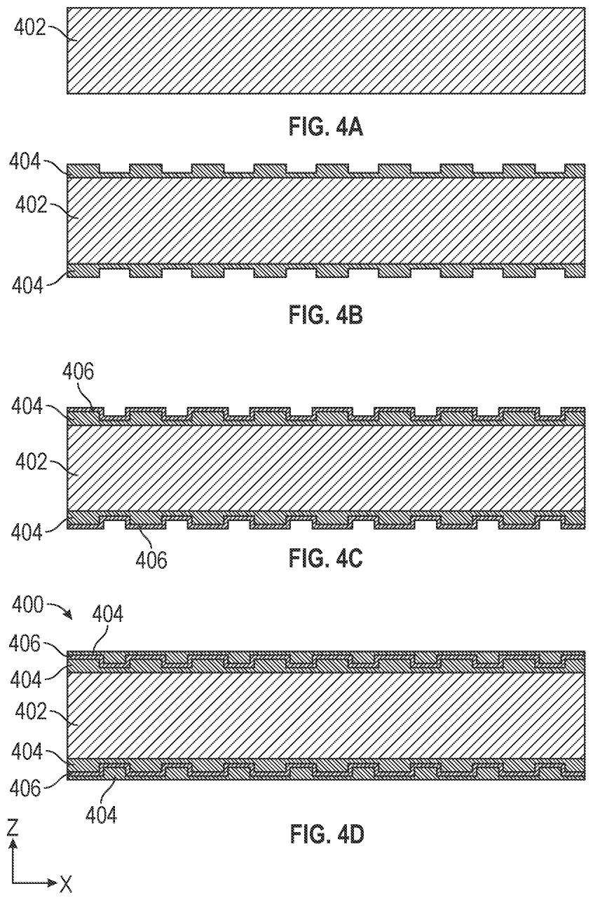

The inductor patch 104b includes inductor structures that are fabricated horizontally on the core of the inductor patch substrate 104b. When the inductor patch 104b is subsequently rotated 90 degrees and embedded vertically in the package substrate 102, however, the horizontal inductor structures become vertical inductor structures that extend through the package substrate 102, which can be used for power delivery (e.g., as described further with respective to inductor patch 300 of FIGS. 3A-E).

The capacitor patch 104c includes capacitor structures that are fabricated horizontally on the core of the capacitor patch substrate 104c. When the capacitor patch 104c is subsequently rotated 90 degrees and embedded vertically in the package substrate 102, however, the horizontal capacitor structures become vertical capacitor structures that extend through the package substrate 102, which can be used for power delivery (e.g., as described further with respective to capacitor patch 400 of FIGS. 4A-D).

Next, the laminated utility patch 106 is rotated 90 degrees and then embedded vertically in a cavity 103 of the package substrate 102, such that the respective patch substrates 104a-d in the utility patch 106 are oriented vertically in the package substrate 102 (e.g., with the respective features on the patch substrates 104a-d extending vertically through the package substrate 102).

Finally, any remaining processing may be performed to complete the IC package 100, such as metallization/interconnect patterning on the package substrate core 102 (e.g., to form traces and vias for interconnects), attaching IC dies or other components, dielectric filling and planarization, and so forth. The completed IC package 100 may include a variety of components and circuitry, including, without limitation, one or more IC dies with processing circuitry, communication circuitry, memory circuitry, and/or storage circuitry. In some embodiments, for example, the IC die(s) may include a central processing unit (CPU), graphics processing unit (GPU), vision processing unit (VPU), microprocessor, microcontroller, field-programmable gate array (FPGA), application-specific integrated circuit (ASIC), input/output (I/O) controller, network interface controller (NIC), memory, and/or solid-state storage, among other examples. Further, in some embodiments, the completed IC package 100 may be attached and/or electrically coupled to a circuit board or another IC substrate or package, and/or may be incorporated into an electronic device or system (e.g., electronic device 1100).

It should be appreciated that the illustrated embodiment is merely shown as an example and other variations are also possible. For example, the number and arrangement of patch substrates 104a-d, and the respective designs and features on each patch substrate 104a-d, may vary depending on the particular use case. In various embodiments, the utility patch 106 may include any number of patch substrates 104 (e.g., one or more), and some or all of the patch substrates 104a-d may have the same design or different designs. Moreover, the size and/or materials of the package substrate 102 and the patch substrates 104 may vary. In some embodiments, for example, the length or width (e.g., X or Y dimension) of a patch substrate 104 (e.g., in its orientation of manufacture) may be substantially equivalent to the thickness (e.g., Z dimension) of the package substrate 102. In this manner, when the patch substrate 104 is rotated 90 degrees and embedded vertically in the package substrate 102, the length or width (e.g., X or Y dimension) of the patch substrate 104 effectively becomes its thickness in the vertical orientation, which matches the thickness of the package substrate 102, thus avoiding thickness mismatch issues. These same variations also apply to the other embodiments described throughout this disclosure (e.g., IC packages 200, 600, 700, patches 300, 400, 500).

Further, throughout this disclosure, a patch substrate may refer to any substrate that may be embedded in another semiconductor substrate or device, and a package substrate may refer to any substrate that may be included in a semiconductor package or assembly.

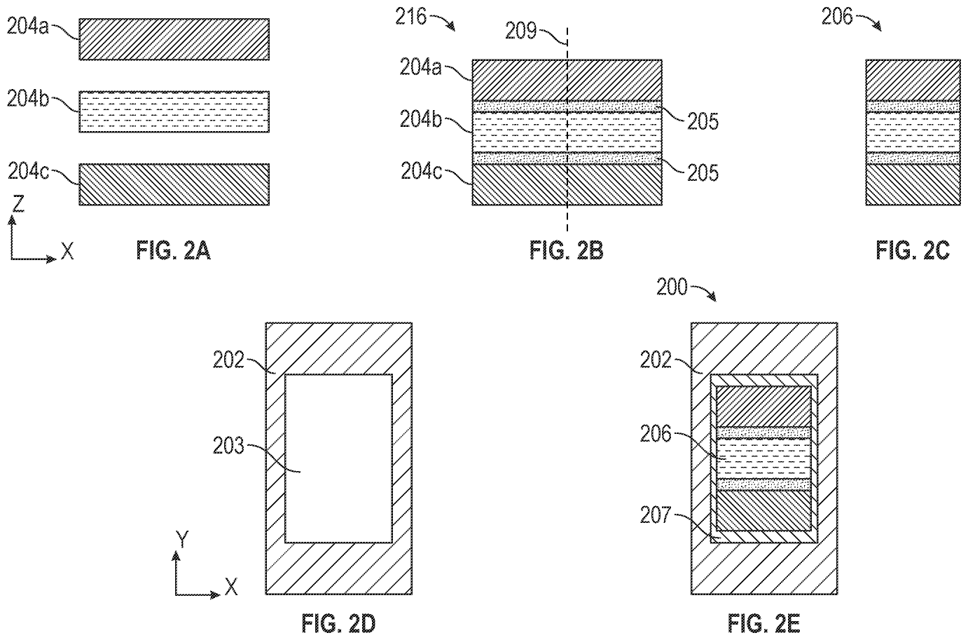

FIGS. 2A-E illustrate a more detailed process flow for forming an integrated circuit (IC) package 200 with an embedded utility patch. In the illustrated embodiment, the IC package 200 includes a utility patch 206 with multiple laminated patch substrates 204a-c embedded vertically in a cavity 203 of a package substrate 202. The process of forming the utility patch 206 is shown in FIGS. 2A-C (e.g., using cross-sectional/profile views taken in the X-Z plane), and the process of embedding the utility patch 206 in the package substrate 202 is shown in FIGS. 2D-E (e.g., using top/plan views taken in the X-Y plane), as described below.

In FIGS. 2A-C, the process of forming the utility patch 206 is shown using cross-sectional/profile views taken in the X-Z plane (e.g., as opposed to the top/plan views taken in the X-Y plane in FIGS. 2D-E).

In FIG. 2A, multiple patch substrates 204a-c are formed and/or received. In the illustrated embodiment, the patch substrates 204a-c are formed at the wafer or panel level. For example, each patch substrate 204a-c may be a wafer or panel with multiple repeating units of a certain type of patch (e.g., inductor patches, capacitor patches, cable patches). Example process flows for forming patch substrates are shown in FIGS. 3A-E, 4A-D, and 5A-D.

In FIG. 2B, the respective patch substrates 204a-c are stacked and laminated together using a laminate 205 (e.g., a pre-preg material such as glass fibers/fabric impregnated with resin) to form a utility patch substrate 216. The utility patch substrate 216 is then diced along one or more cut lines 209 to singulate the individual utility patches 206 on the substrate 216.

In FIG. 2C, a singulated utility patch 206 is shown (e.g., after the utility patch substrate 216 is diced in FIG. 2B).

In FIGS. 2D-E, the process of embedding the singulated utility patch 206 in a package substrate 202 is shown using top/plan views taken in the X-Y plane (e.g., as opposed to the cross-sectional/profile views taken in the X-Z plane in FIGS. 2A-C).

In FIG. 2D, a package substrate 202 (e.g., a substrate core) is received. The package substrate 202 may be any type of substrate/substrate core, such as an organic substrate or a glass core substrate. In some embodiments, the package substrate 202 may be received with a pre-formed cavity 203 in the substrate core, or alternatively, the package substrate 202 may be received without a cavity and a cavity 203 may be subsequently formed in the substrate core. In various embodiments, the cavity 203 may be formed all the way through the package substrate core 202 (e.g., a bottomless cavity) or only partially through the package substrate core 202 (e.g., a bottomed cavity).

In FIG. 2E, the utility patch 206 from FIG. 2C is rotated 90 degrees (e.g., from a horizontal orientation to a vertical orientation) and then embedded vertically in the cavity 203 of the package substrate 202 using a laminate 207. In some embodiments, the laminate 207 may be a dielectric and/or insulating film such as Ajinomoto Build-Up Film (ABF), mold materials, and/or plugging materials.

In this manner, the respective patch substrates 204a-c in the utility patch 206 are oriented vertically in the cavity 203 of the package substrate 202 with their respective features extending vertically through or within the cavity 203. For example, the package substrate 200 is oriented on a horizontal plane (e.g., the same orientation in which it is fabricated), while the respective patch substrates 204a-c are oriented on vertical planes (e.g., orthogonal to the orientation in which they are fabricated), where the horizontal and vertical planes are substantially orthogonal to each other.

The utility patch 206 is depicted from the same perspective in FIGS. 2C and 2E even though the utility patch 206 has been rotated 90 degrees in FIG. 2E relative to FIG. 2C. This is because FIG. 2C shows a cross-sectional/profile view of the utility patch 206 before the rotation, while FIG. 2E shows a top/plan view of the utility patch 206 after the rotation (e.g., vertically embedded in the package substrate 202). After the rotation, the cross-sectional/profile view of the utility patch 206 becomes the top/plan view, which is why the utility patch 206 is shown from the same perspective in FIGS. 2C and 2E.

Finally, any remaining processing may be performed to complete the IC package 200 (e.g., as described above with respect to IC package 100).

FIGS. 3A-E illustrate an example process flow for forming an inductor patch 300. The illustrated process flow is shown using cross-sectional/profile views taken in the X-Z plane. In some embodiments, the resulting inductor patch 300 may be embedded vertically in another semiconductor substrate (e.g., as described further throughout this disclosure).

In FIG. 3A, a substrate core 302 is received.

In FIG. 3B, a magnetic layer 304 is formed over the substrate core 302 (e.g., above and/or below) by depositing a high-permeability magnetic alloy film over the core 302. In some embodiments, the film used to form the magnetic layer 304 may include iron (Fe) and/or cobalt (Co). Next, an insulation layer 306 is formed over the magnetic layer 304 (e.g., above and/or below) by depositing a passivating/insulating film over the magnetic layer 304 for protection and insulation. In some embodiments, the film used to form the insulation layer 306 may include silicon (Si) and/or oxygen (O) (e.g., an oxide of silicon such as silica/SiO₂) or another dielectric material.

In FIG. 3C, conductive traces 308 are formed over the insulation layer 306 (e.g., above and/or below) on the substrate core 302. For example, a conductive layer may be formed over the insulation layer 306 by depositing a conductive film (e.g., a metal or alloy that includes copper (Cu)), and the conductive layer may then be patterned into horizontal traces 308. The traces 308 may have varying line width/spacing in different embodiments, such as 67.5/100 μm, 67.5/67.5 μm, 8/8 μm, or 5/5 μm, although other line widths/spacing are also possible.

In FIG. 3D, another insulation layer 306 is formed over the traces 308 (e.g., above and/or below) by depositing a passivating/insulating film (e.g., a dielectric film that includes silicon (Si) and/or oxygen (O), such as silica/SiO₂ or another dielectric material), and another magnetic layer 304 is formed over the insulation layer 306 (e.g., above and/or below) by depositing a high-permeability magnetic alloy film (e.g., a film that includes iron (Fc) and/or cobalt (Co)).

In FIG. 3E, the layers on the substrate core 302 are laminated or coated with a protective layer 310. For example, the protective layer 310 is formed over the magnetic layer 304 (e.g., above and/or below) to fill the spacing between the traces 308. The protective layer 310 serves as protection for the other layers on the substrate core 302 and also reduces loss. The protective layer 310 may be formed by depositing a dielectric and/or insulating film, such as Ajinomoto Build-Up Film (ABF) and/or photo-imageable dielectric (PID) film. In some embodiments, the film may be a spray-coated liquid film to reduce the thickness of the protective layer 310 (e.g., spray-coated liquid ABF).

At this point, the inductor patch substrate 300 may be complete. For example, the resulting inductor patch 300 includes traces 308 surrounded by magnetic layers 304, thus forming horizontal inductor structures on the inductor patch 300.

These inductor structures are oriented horizontally on the inductor patch 300. However, when the inductor patch 300 is rotated 90 degrees and embedded vertically in another semiconductor substrate, the horizontal inductor structures on the inductor patch 300 become vertical inductor structures, as they extend vertically through the substrate they are embedded in (e.g., as described further throughout this disclosure).

Inductor structures can be fabricated on a substrate with significantly higher density in a horizontal orientation compared to a vertical orientation. Thus, by fabricating the inductor structures horizontally on the inductor patch 300 and then rotating and embedding the patch 300 vertically in a package substrate, the inductor patch 300 enables the package substrate to have vertical inductor structures with significantly higher density than if they were fabricated directly in the package substrate in a vertical orientation.

The inductor patch 300 provides various advantages, including higher inductance and smaller footprint. For example, the formula for inductance of a wire coil is

$$L = \frac{μ {N}^{2} A}{l} ,$$

where L=inductance, μ=permeability of core material, N=number of turns in coil, A=area of coil, and l=length of coil. In the illustrated embodiment, the inductor patch 300 has high-permeability magnetic materials (e.g., iron (Fc)/cobalt (Co)), more turns (N), and smaller pitch (l), which translates to higher inductance.

FIGS. 4A-D illustrate an example process flow for forming a capacitor patch 400. The illustrated process flow is shown using cross-sectional/profile views taken in the X-Z plane. In some embodiments, the resulting capacitor patch 400 may be embedded vertically in another semiconductor substrate (e.g., as described further throughout this disclosure).

In FIG. 4A, a substrate core 402 is received.

In FIG. 4B, a conductive layer 404 patterned with traces and plating is formed over the substrate core 402 (e.g., above and/or below). For example, conductive film may be deposited to form a conductive layer over the substrate core 402, the conductive layer may be patterned into traces, and conductive film may be deposited once again to form a thin layer of conductive plating over and/or between the traces. In some embodiments, the conductive film(s) used to form the traces and/or plating in the conductive layer 404 may include one or more metals such as copper (Cu) (e.g., electroless (eless) and/or electrolytic (elytic) copper film). Further, in some embodiments, the traces may have line width/spacing of 25/35 μm, and the plating may have a thickness of 5 μm, although other line widths/spacing and thicknesses are also possible (e.g., 67.5/100 μm, 67.5/67.5 μm, 8/8 μm, 5/5 μm).

In FIG. 4C, a dielectric layer 406 is formed over the patterned conductive layer 404 (e.g., above and/or below) by depositing a dielectric film. In some embodiments, the dielectric film may include a dielectric material, such as a high-Dk dielectric material that includes barium (Ba), titanium (Ti), and/or oxygen (O) (e.g., barium titanate (BaTiO₃)).

In FIG. 4D, another conductive layer 404 is formed over the dielectric layer 406 (e.g., above and/or below). For example, the conductive layer 404 may be formed by forming a thin conductive layer over the dielectric layer 406 followed by conductive plating. In some embodiments, the material(s) used to form the conductive layer 404 may include one or more metals, such as aluminum (Al) and/or copper (Cu). For example, the thin conductive layer may be formed from a material that includes aluminum (Al) (e.g., a thin aluminum layer), and the conductive plating may be formed from a material that includes copper (Cu) (e.g., copper plating).

At this point, the capacitor patch substrate 400 may be complete. For example, the resulting capacitor patch 400 includes multiple conductive layers 404 (e.g., electrodes) separated by a dielectric layer 406, thus forming metal-insulator-metal capacitor structures.

These capacitor structures are oriented horizontally on the capacitor patch 400. However, when the capacitor patch 400 is rotated 90 degrees and embedded vertically in another semiconductor substrate, the horizontal capacitor structures on the capacitor patch 400 become vertical capacitor structures, as they extend vertically through the substrate they are embedded in (e.g., as described further throughout this disclosure).

Capacitor structures can be fabricated on a substrate with significantly higher density in a horizontal orientation compared to a vertical orientation. Thus, by fabricating the capacitor structures horizontally on the capacitor patch 400 and then rotating and embedding the patch 400 vertically in a package substrate, the capacitor patch 400 enables the package substrate to have vertical capacitor structures with significantly higher density than if they were fabricated directly in the package substrate in a vertical orientation.

FIGS. 5A-D illustrate an example process flow for forming a cable patch 500. The illustrated process flow is shown using cross-sectional/profile views taken in the X-Z plane. In some embodiments, the resulting cable patch 500 may be embedded vertically in another semiconductor substrate (e.g., as described further throughout this disclosure).

In FIG. 5A, a substrate core 502 is received.

In FIG. 5B, a conductive layer 504 is formed over the substrate core 502 (e.g., above and/or below) by depositing conductive film over the core 502. In some embodiments, the conductive film may include one or more metals (e.g., copper (Cu)).

In FIG. 5C, the conductive layer 504 is patterned into horizontal conductive traces 504 (e.g., using photolithography techniques and dry film resist). The traces 504 may have varying line width/spacing in different embodiments, such as 67.5/100 μm, 67.5/67.5 μm, 8/8 μm, or 5/5 μm, although other line widths/spacing are also possible.

In FIG. 5D, a protective layer 506 is formed over the conductive traces 504 (e.g., above and/or below) to protect the traces 504. For example, the protective layer 506 may be formed by laminating or coating the conductive traces 504 with a dielectric and/or insulating film, such as Ajinomoto Build-Up Film (ABF). In some embodiments, a spray-coated liquid film may be used to reduce the thickness of the protective layer 506 (e.g., spray-coated liquid ABF).

At this point, the cable patch substrate 500 may be complete. For example, the resulting cable patch 500 includes conductive traces 504 above and/or below the substrate core 502 (e.g., protected by a laminate 506).

The traces 504 are oriented horizontally on the cable patch 500. However, when the cable patch 500 is rotated 90 degrees and embedded vertically in another semiconductor substrate, the horizontal traces 504 on the cable patch 500 become vertical traces 504, as they extend vertically through the substrate they are embedded in, effectively functioning as plated through holes (PTHs) or vias (e.g., as described further throughout this disclosure).

Traces can be fabricated horizontally on a substrate with significantly higher density than vias or through holes formed vertically through the substrate. Thus, by fabricating the traces 504 horizontally on the cable patch 500 and then rotating and embedding the patch 500 vertically in a package substrate, the cable patch 500 enables the package substrate to have vertical traces 504 with significantly higher density than if plated through holes or vias were fabricated directly in the package substrate.

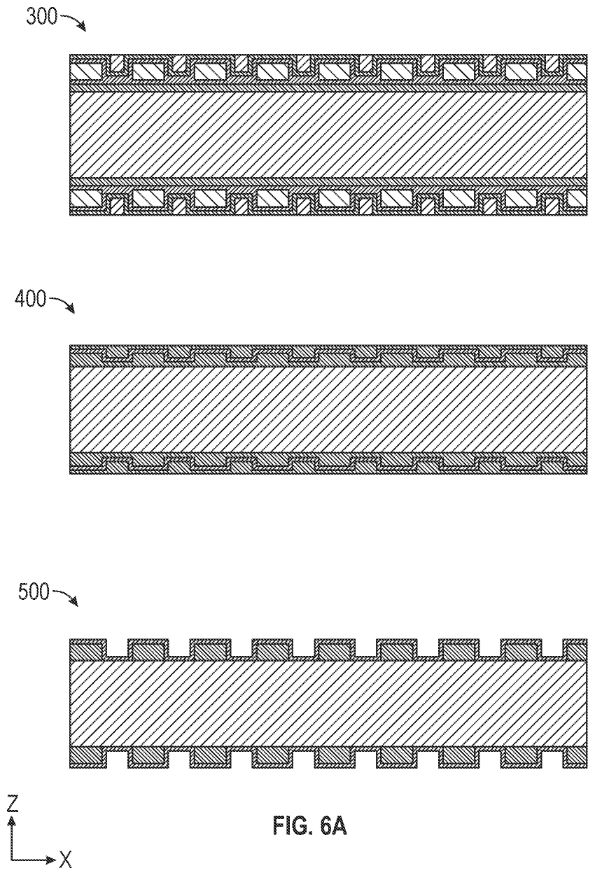

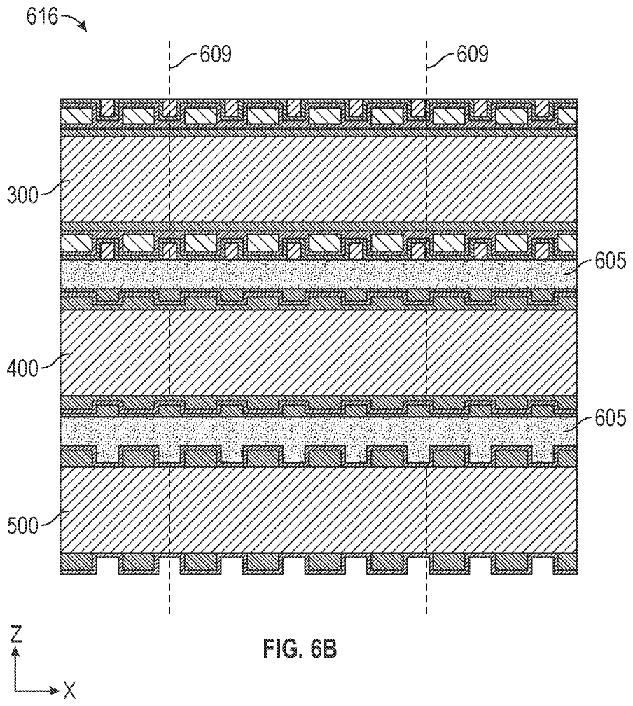

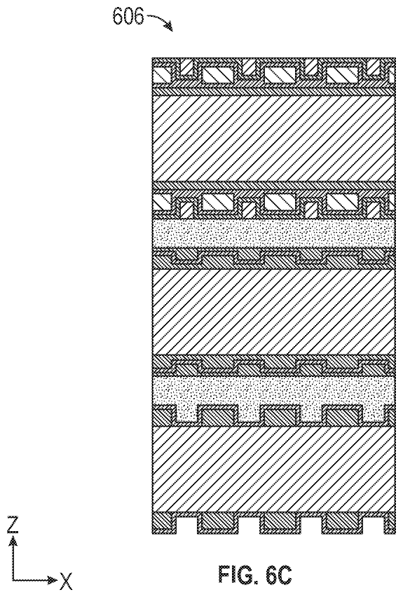

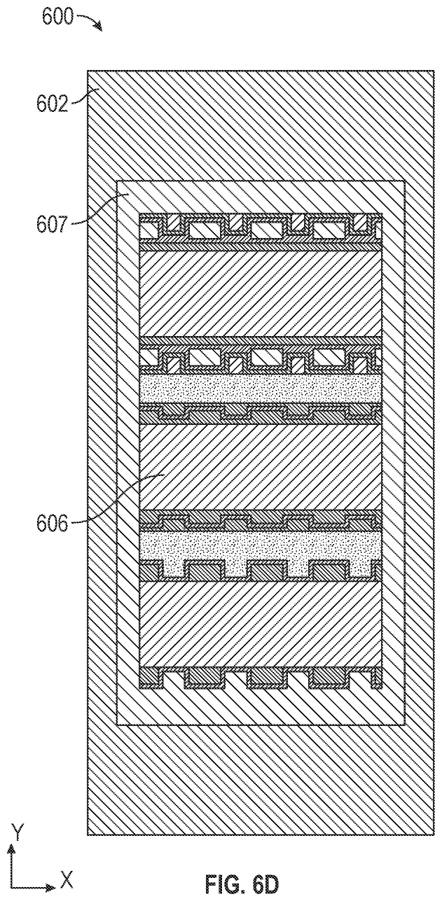

FIGS. 6A-D illustrate an example process flow for forming an integrated circuit (IC) package 600 with an embedded heterogenous utility patch. In the illustrated embodiment, the IC package 600 includes a utility patch 606 with multiple laminated patch substrates 300, 400, 500 embedded vertically in a cavity of a package substrate 602. In particular, the utility patch 606 is formed using the respective patch substrates 300, 400, 500 from the process flows of FIGS. 3A-E, 4A-D, and 5A-D, respectively (e.g., inductor patch 300, capacitor patch 400, cable patch 500).

The process of forming the utility patch 606 is shown in FIGS. 6A-C (e.g., using cross-sectional/profile views taken in the X-Z plane), and the process of embedding the utility patch 606 in the package substrate 602 is shown in FIG. 6D (e.g., using a top/plan view taken in the X-Y plane).

In FIG. 6A, multiple patch substrates 300, 400, 500 are received, including the inductor patch substrate 300 from FIGS. 3A-E, the capacitor patch substrate 400 from FIGS. 4A-D, and the cable patch substrate 500 from FIGS. 5A-D. In some embodiments, these patch substrates 300, 400, 500 may be wafer- or panel-level substrates (e.g., with multiple repeating units of inductor patches, capacitor patches, and cable patches, respectively).

In FIG. 6B, the respective patch substrates 300, 400, 500 are stacked and laminated together using a laminate 605 (e.g., a pre-preg material such as glass fibers/fabric impregnated with resin) to form a utility patch substrate 616. The utility patch substrate 616 is then diced along multiple cut lines 609 to singulate the individual utility patches 606 on the substrate 616.

In FIG. 6C, a singulated utility patch 606 is shown (e.g., after the utility patch substrate 616 is diced in FIG. 6B).

In FIG. 6D, the singulated utility patch 606 is embedded vertically in a package substrate 602, which is shown using a top/plan view taken in the X-Y plane (e.g., as opposed to the cross-sectional/profile views taken in the X-Z plane in FIGS. 6A-C). The package substrate 602 may be any type of substrate/substrate core, such as an organic substrate or a glass core substrate. Moreover, the utility patch 606 from FIG. 6C is rotated 90 degrees (e.g., from a horizontal orientation to a vertical orientation) and then embedded vertically in a cavity (not shown) of the package substrate 602 using a laminate 607 (e.g., a dielectric and/or insulating film such as Ajinomoto Build-Up Film (ABF)).

In this manner, the respective patch substrates 300, 400, 500 in the utility patch 606 are oriented vertically within the package substrate 602 with their respective features (e.g., inductors, capacitors, traces) extending vertically through or within the package substrate 602.

The utility patch 606 is depicted from the same perspective in FIGS. 6C and 6D even though the utility patch 606 has been rotated 90 degrees in FIG. 6D relative to FIG. 6C. This is because FIG. 6C shows a cross-sectional/profile view of the utility patch 606 before the rotation, while FIG. 6D shows a top/plan view of the utility patch 606 after the rotation (e.g., vertically embedded in the package substrate 602). After the rotation, the cross-sectional/profile view of the utility patch 606 becomes the top/plan view, which is why the utility patch 606 is shown from the same perspective in FIGS. 6C and 6D.

Finally, any remaining processing may be performed to complete the IC package 600 (e.g., as described above with respect to IC package 100).

The illustrated embodiment provides significant customizability in terms of patch structure and size (e.g., in addition to the other advantages described throughout this disclosure). For example, the number and arrangement of patch substrates in the utility patch, the respective designs and features on each patch substrate, and the size and materials of each patch substrate, may vary depending on the particular use case. In various embodiments, the utility patch may include any number of patch substrates (e.g., one or more), and some or all of the patch substrates may have the same design or different designs. While the illustrated embodiment shows a utility patch 606 with inductor, capacitor, and cable patch substrates 300, 400, 500, other embodiments may include other combinations and variations of patch substrates, including multiple inductor patch substrates 300, multiple capacitor patch substrates 400, or multiple cable patch substrates 500, and/or other types of patch substrates, including patch substrates with a combination of different features (e.g., a patch substrate with inductors, capacitors, and/or traces).

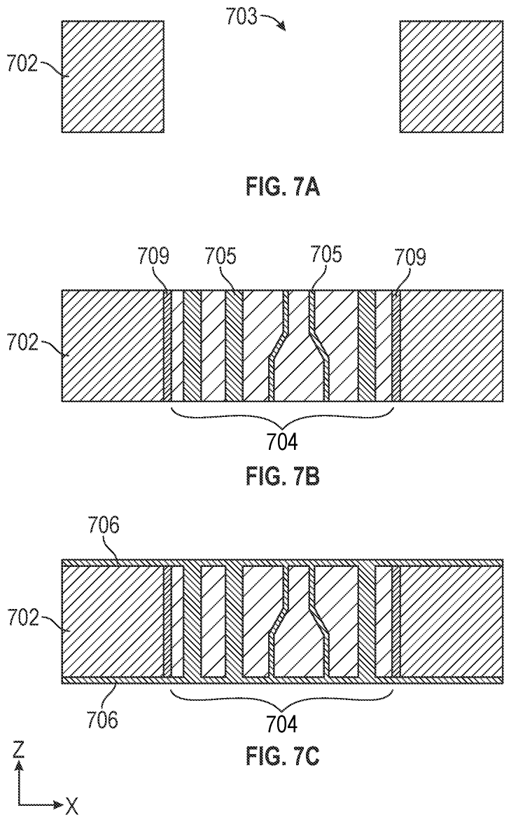

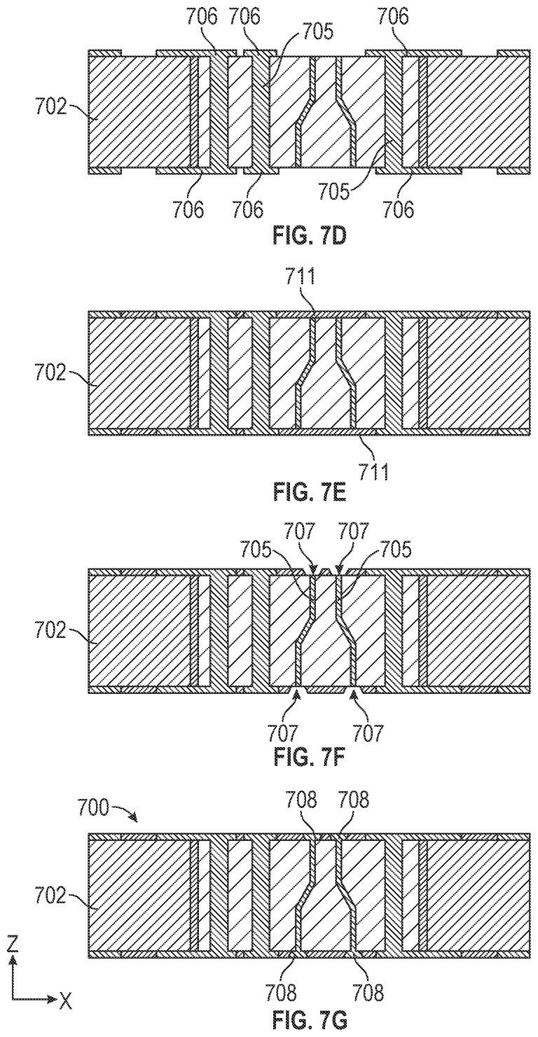

FIGS. 7A-G illustrate an example process flow for forming an integrated circuit (IC) package 700 with an embedded cable patch 704. In the illustrated embodiment, the IC package 700 includes a cable patch 704 embedded vertically in a cavity 703 of a package substrate 702. The illustrated process flow is shown using cross-sectional/profile views taken in the X-Z plane.

In FIG. 7A, a substrate core 702 is received, and a cavity 703 is drilled in the substrate core 702.

In FIG. 7B, a cable patch 704 is received, rotated 90 degrees (e.g., horizontal to vertical), and then embedded in the cavity 703 of the substrate core 702 using a laminate 709 (e.g., ABF, pre-preg, or another dielectric film), and grinding is performed. In the illustrated embodiment, the cable patch 704 includes conductive traces 705 of varying widths, which were fabricated horizontally on the cable patch 704 but now extend vertically through the substrate core 702 due to the rotation of the cable patch 704 prior to embedding.

In FIG. 7C, conductive plating 706 is formed over the substrate core 702 (and the embedded cable patch 704) (e.g., 35 μm copper plating).

In FIG. 7D, the conductive plating 706 is patterned to form pads 706 over some of the traces 705 in the cable patch 704. However, some of the traces 705 may be too small for pads, and thus vias may be drilled on top of those traces 705 in FIGS. 7E-G, as described below.

In FIG. 7E, the substrate core 702 is laminated with a dielectric laminate 711 such as ABF.

In FIG. 7F, via holes 707 are drilled in the laminate 711 over the thin traces 705 in the cable patch 704.

In FIG. 7G, the via holes 707 are plated with a conductive material (e.g., copper) to form plated vias 708 over the thin traces 705.

Finally, any remaining processing may be performed to complete the IC package 700 (e.g., as described above with respect to IC package 100).

### Example Integrated Circuit Embodiments

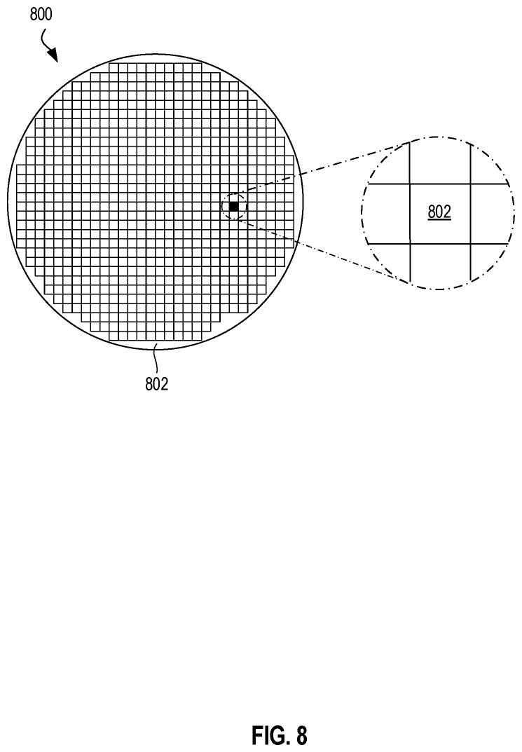

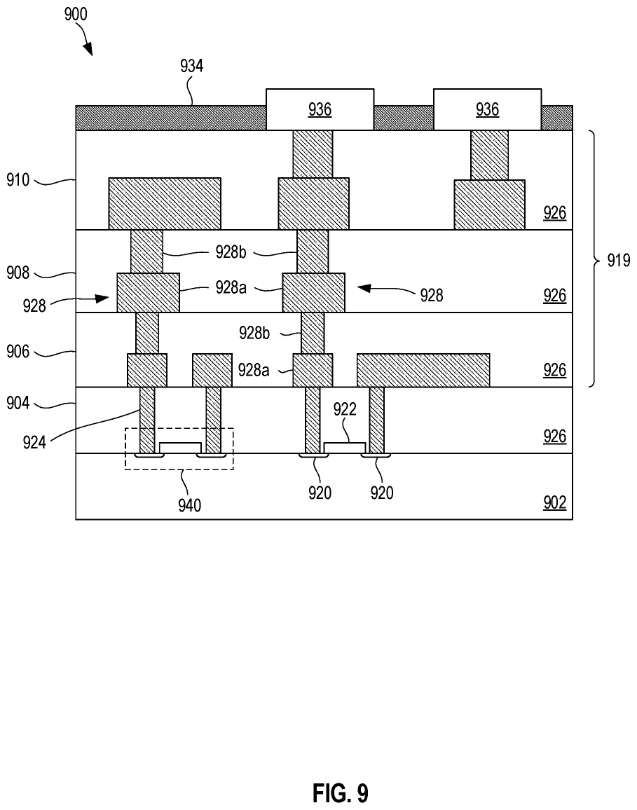

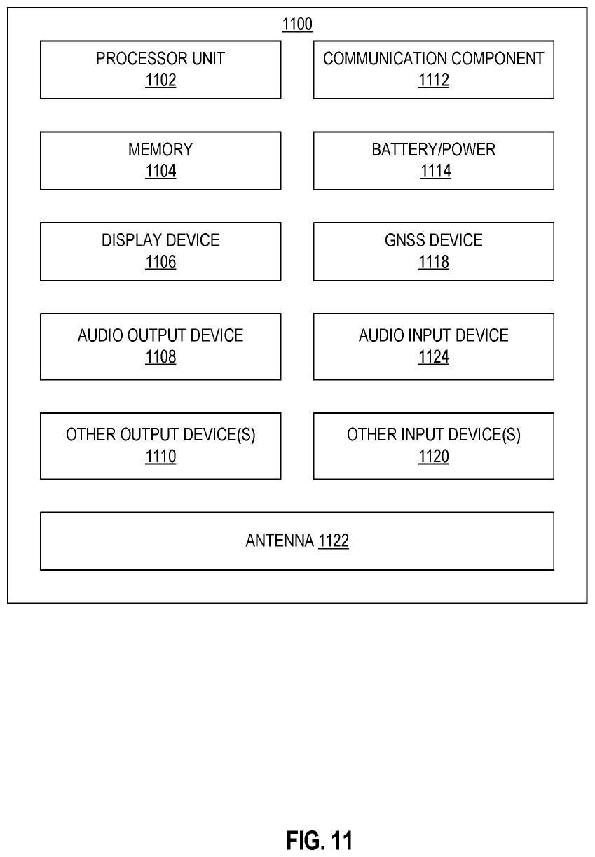

FIG. 8 is a top view of a wafer 800 and dies 802 that may be included in, or may include, any of the embodiments disclosed herein. In some embodiments, for example, the wafer 800 may include dies 802 with cavities for embedded utility patches or dies 802 used as utility patches. The wafer 800 may be composed of semiconductor material and may include one or more dies 802 having integrated circuit structures formed on a surface of the wafer 800. The individual dies 802 may be a repeating unit of an integrated circuit product that includes any suitable integrated circuit. After the fabrication of the semiconductor product is complete, the wafer 800 may undergo a singulation process in which the dies 802 are separated from one another to provide discrete “chips” of the integrated circuit product. The die 802 may be any of the dies disclosed herein. The die 802 may include one or more transistors (e.g., some of the transistors 940 of FIG. 9, discussed below), supporting circuitry to route electrical signals to the transistors, passive components (e.g., signal traces, resistors, capacitors, or inductors), and/or any other integrated circuit components. In some embodiments, the wafer 800 or the die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 802. For example, a memory array formed by multiple memory devices may be formed on a same die 802 as a processor unit (e.g., the processor unit 1102 of FIG. 11) or other logic that is configured to store information in the memory devices or execute instructions stored in the memory array. Various ones of the microelectronic assemblies disclosed herein may be manufactured using a dic-to-wafer assembly technique in which some dies are attached to a wafer 800 that include others of the dies, and the wafer 800 is subsequently singulated.

FIG. 9 is a cross-sectional side view of an integrated circuit device 900 that may be included in any of the embodiments disclosed herein (e.g., in any of the dies). One or more of the integrated circuit devices 900 may be included in one or more dies 802 (FIG. 8). The integrated circuit device 900 may be formed on a die substrate 902 (e.g., the wafer 800 of FIG. 8) and may be included in a die (e.g., the die 802 of FIG. 8). The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit device 900 may be used. The die substrate 902 may be part of a singulated die (e.g., the dies 802 of FIG. 8) or a wafer (e.g., the wafer 800 of FIG. 8).

The integrated circuit device 900 may include one or more device layers 904 disposed on the die substrate 902. The device layer 904 may include features of one or more transistors 940 (e.g., metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

A transistor 940 may include a gate 922 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may consist of a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit device 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuit devices having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page from the perspective of FIG. 9. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines 928 of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit device 900 (i.e., farther away from the device layer 904) may be thicker that the interconnect layers that are lower in the metallization stack 919, with lines 928a and vias 928b in the higher interconnect layers being thicker than those in the lower interconnect layers.

The integrated circuit device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit device 900 with another component (e.g., a printed circuit board). The integrated circuit device 900 may include additional or alternate structures to route the electrical signals from the interconnect layers 906-910; for example, the conductive contacts 936 may include other analogous features (e.g., posts) that route the electrical signals to external components. The conductive contacts 936 may serve as any of the conductive contacts described throughout this disclosure.

In some embodiments in which the integrated circuit device 900 is a double-sided die, the integrated circuit device 900 may include another metallization stack (not shown) on the opposite side of the device layer(s) 904. This metallization stack may include multiple interconnect layers as discussed above with reference to the interconnect layers 906-910, to provide conductive pathways (e.g., including conductive lines and vias) between the device layer(s) 904 and additional conductive contacts (not shown) on the opposite side of the integrated circuit device 900 from the conductive contacts 936. These additional conductive contacts may serve as any of the conductive contacts described throughout this disclosure.

In other embodiments in which the integrated circuit device 900 is a double-sided die, the integrated circuit device 900 may include one or more through silicon vias (TSVs) through the die substrate 902; these TSVs may make contact with the device layer(s) 904, and may provide conductive pathways between the device layer(s) 904 and additional conductive contacts (not shown) on the opposite side of the integrated circuit device 900 from the conductive contacts 936. These additional conductive contacts may serve as any of the conductive contacts described throughout this disclosure. In some embodiments, TSVs extending through the substrate can be used for routing power and ground signals from conductive contacts on the opposite side of the integrated circuit device 900 from the conductive contacts 936 to the transistors 940 and any other components integrated into the die 900, and the metallization stack 919 can be used to route I/O signals from the conductive contacts 936 to transistors 940 and any other components integrated into the die 900.

Multiple integrated circuit devices 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit dic. Conductive contacts can provide additional connections between adjacent integrated circuit dies in the stack. In some embodiments, the conductive contacts can be fine-pitch solder bumps (microbumps).

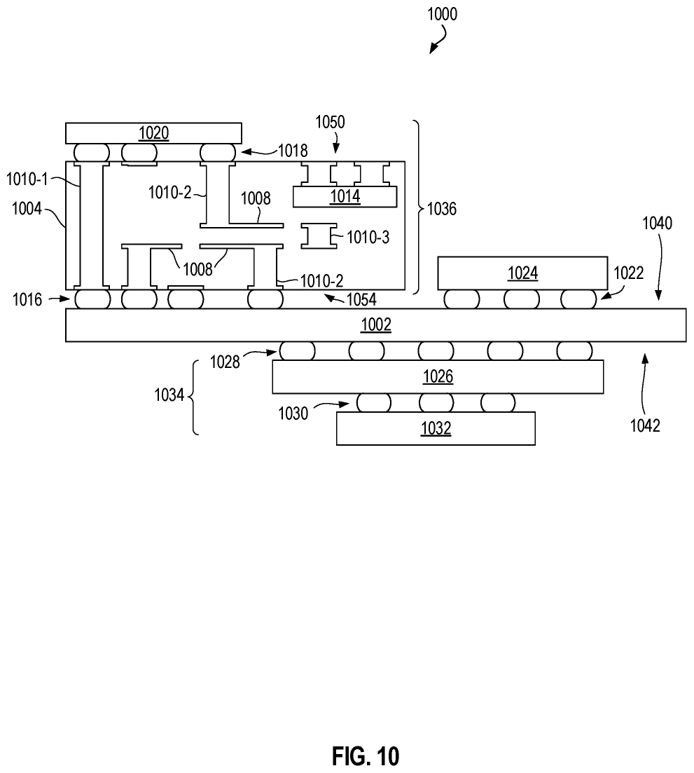

FIG. 10 is a cross-sectional side view of an integrated circuit device assembly 1000 that may include any of the embodiments disclosed herein (e.g., a utility patch vertically embedded in one of the substrates of assembly 1000). In some embodiments, the integrated circuit device assembly 1000 may be a microelectronic assembly. The integrated circuit device assembly 1000 includes a number of components disposed on a circuit board 1002 (which may be a motherboard, system board, mainboard, etc.). The integrated circuit device assembly 1000 includes components disposed on a first face 1040 of the circuit board 1002 and an opposing second face 1042 of the circuit board 1002; generally, components may be disposed on one or both faces 1040 and 1042. Any of the integrated circuit components discussed below with reference to the integrated circuit device assembly 1000 may take the form of any suitable ones of the embodiments of the microelectronic assemblies disclosed herein.

In some embodiments, the circuit board 1002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1002. In other embodiments, the circuit board 1002 may be a non-PCB substrate. The integrated circuit device assembly 1000 illustrated in FIG. 10 includes a package-on-interposer structure 1036 coupled to the first face 1040 of the circuit board 1002 by coupling components 1016. The coupling components 1016 may electrically and mechanically couple the package-on-interposer structure 1036 to the circuit board 1002, and may include solder balls (as shown in FIG. 10), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1016 may serve as the coupling components illustrated or described for any of the substrate assembly or substrate assembly components described herein, as appropriate.

The package-on-interposer structure 1036 may include an integrated circuit component 1020 coupled to an interposer 1004 by coupling components 1018. The coupling components 1018 may take any suitable form for the application, such as the forms discussed above with reference to the coupling components 1016. Although a single integrated circuit component 1020 is shown in FIG. 10, multiple integrated circuit components may be coupled to the interposer 1004; indeed, additional interposers may be coupled to the interposer 1004. The interposer 1004 may provide an intervening substrate used to bridge the circuit board 1002 and the integrated circuit component 1020.

The integrated circuit component 1020 may be a packaged or unpackaged integrated circuit product that includes one or more integrated circuit dies (e.g., the die 802 of FIG. 8, the integrated circuit device 900 of FIG. 9) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1020, a single monolithic integrated circuit die comprises solder bumps attached to contacts on the die. The solder bumps allow the die to be directly attached to the interposer 1004. The integrated circuit component 1020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1020 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1020 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-dic interconnect bridges (EMIBs)), or combinations thereof.

Generally, the interposer 1004 may spread connections to a wider pitch or reroute a connection to a different connection. For example, the interposer 1004 may couple the integrated circuit component 1020 to a set of ball grid array (BGA) conductive contacts of the coupling components 1016 for coupling to the circuit board 1002. In the embodiment illustrated in FIG. 10, the integrated circuit component 1020 and the circuit board 1002 are attached to opposing sides of the interposer 1004; in other embodiments, the integrated circuit component 1020 and the circuit board 1002 may be attached to a same side of the interposer 1004. In some embodiments, three or more components may be interconnected by way of the interposer 1004.

In some embodiments, the interposer 1004 may be formed as a PCB, including multiple metal layers separated from one another by layers of dielectric material and interconnected by electrically conductive vias. In some embodiments, the interposer 1004 may be formed of an epoxy resin, a fiberglass-reinforced epoxy resin, an epoxy resin with inorganic fillers, a ceramic material, or a polymer material such as polyimide. In some embodiments, the interposer 1004 may be formed of alternate rigid or flexible materials that may include the same materials described above for use in a semiconductor substrate, such as silicon, germanium, and other group III-V and group IV materials. The interposer 1004 may include metal interconnects 1008 and vias 1010, including but not limited to through hole vias 1010-1 (that extend from a first face 1050 of the interposer 1004 to a second face 1054 of the interposer 1004), blind vias 1010-2 (that extend from the first or second faces 1050 or 1054 of the interposer 1004 to an internal metal layer), and buried vias 1010-3 (that connect internal metal layers).

In some embodiments, the interposer 1004 can comprise a silicon interposer. Through silicon vias (TSV) extending through the silicon interposer can connect connections on a first face of a silicon interposer to an opposing second face of the silicon interposer. In some embodiments, an interposer 1004 comprising a silicon interposer can further comprise one or more routing layers to route connections on a first face of the interposer 1004 to an opposing second face of the interposer 1004.

The interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1004. The package-on-interposer structure 1036 may take the form of any of the package-on-interposer structures known in the art. In embodiments where the interposer is a non-printed circuit board

The integrated circuit device assembly 1000 may include an integrated circuit component 1024 coupled to the first face 1040 of the circuit board 1002 by coupling components 1022. The coupling components 1022 may take the form of any of the embodiments discussed above with reference to the coupling components 1016, and the integrated circuit component 1024 may take the form of any of the embodiments discussed above with reference to the integrated circuit component 1020.

The integrated circuit device assembly 1000 illustrated in FIG. 10 includes a package-on-package structure 1034 coupled to the second face 1042 of the circuit board 1002 by coupling components 1028. The package-on-package structure 1034 may include an integrated circuit component 1026 and an integrated circuit component 1032 coupled together by coupling components 1030 such that the integrated circuit component 1026 is disposed between the circuit board 1002 and the integrated circuit component 1032. The coupling components 1028 and 1030 may take the form of any of the embodiments of the coupling components 1016 discussed above, and the integrated circuit components 1026 and 1032 may take the form of any of the embodiments of the integrated circuit component 1020 discussed above. The package-on-package structure 1034 may be configured in accordance with any of the package-on-package structures known in the art.

FIG. 11 is a block diagram of an example electrical device 1100 that may include one or more of the embodiments disclosed herein. For example, any suitable ones of the components of the electrical device 1100 may include one or more integrated circuits with utility patches vertically embedded in a cavity, integrated circuit device assemblies 1000, integrated circuit components 1020, integrated circuit devices 900, or integrated circuit dies 802 disclosed herein. A number of components are illustrated in FIG. 11 as included in the electrical device 1100, but any one or more of these components may be omitted or duplicated, as suitable for the application. In some embodiments, some or all of the components included in the electrical device 1100 may be attached to one or more motherboards mainboards, or system boards. In some embodiments, one or more of these components are fabricated onto a single system-on-a-chip (SoC) die.

Additionally, in various embodiments, the electrical device 1100 may not include one or more of the components illustrated in FIG. 11, but the electrical device 1100 may include interface circuitry for coupling to the one or more components. For example, the electrical device 1100 may not include a display device 1106, but may include display device interface circuitry (e.g., a connector and driver circuitry) to which a display device 1106 may be coupled. In another set of examples, the electrical device 1100 may not include an audio input device 1124 or an audio output device 1108, but may include audio input or output device interface circuitry (e.g., connectors and supporting circuitry) to which an audio input device 1124 or audio output device 1108 may be coupled.

The electrical device 1100 may include one or more processor units 1102 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1100 may include a memory 1104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1104 may include memory that is located on the same integrated circuit die as the processor unit 1102. This memory may be used as cache memory (e.g., Level 1 (L1), Level 2 (L2), Level 3 (L3), Level 4 (LA), Last Level Cache (LLC)) and may include embedded dynamic random access memory (eDRAM) or spin transfer torque magnetic random access memory (STT-MRAM).

In some embodiments, the electrical device 1100 can comprise one or more processor units 1102 that are heterogeneous or asymmetric to another processor unit 1102 in the electrical device 1100. There can be a variety of differences between the processing units 1102 in a system in terms of a spectrum of metrics of merit including architectural, microarchitectural, thermal, power consumption characteristics, and the like. These differences can effectively manifest themselves as asymmetry and heterogeneity among the processor units 1102 in the electrical device 1100.

In some embodiments, the electrical device 1100 may include a communication component 1112 (e.g., one or more communication components). For example, the communication component 1112 can manage wireless communications for the transfer of data to and from the electrical device 1100. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1112 may operate in accordance with other wireless protocols in other embodiments. The electrical device 1100 may include an antenna 1122 to facilitate wireless communications and/or to receive other wireless communications (such as AM or FM radio transmissions).

In some embodiments, the communication component 1112 may manage wired communications, such as electrical, optical, or any other suitable communication protocols (e.g., IEEE 802.3 Ethernet standards). As noted above, the communication component 1112 may include multiple communication components. For instance, a first communication component 1112 may be dedicated to shorter-range wireless communications such as Wi-Fi or Bluetooth, and a second communication component 1112 may be dedicated to longer-range wireless communications such as global positioning system (GPS), EDGE, GPRS, CDMA, WiMAX, LTE, EV-DO, or others. In some embodiments, a first communication component 1112 may be dedicated to wireless communications, and a second communication component 1112 may be dedicated to wired communications.

The electrical device 1100 may include battery/power circuitry 1114. The battery/power circuitry 1114 may include one or more energy storage devices (e.g., batteries or capacitors) and/or circuitry for coupling components of the electrical device 1100 to an energy source separate from the electrical device 1100 (e.g., AC line power).

The electrical device 1100 may include a display device 1106 (or corresponding interface circuitry, as discussed above). The display device 1106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1100 may include an audio output device 1108 (or corresponding interface circuitry, as discussed above). The audio output device 1108 may include any embedded or wired or wirelessly connected external device that generates an audible indicator, such speakers, headsets, or earbuds.

The electrical device 1100 may include an audio input device 1124 (or corresponding interface circuitry, as discussed above). The audio input device 1124 may include any embedded or wired or wirelessly connected device that generates a signal representative of a sound, such as microphones, microphone arrays, or digital instruments (e.g., instruments having a musical instrument digital interface (MIDI) output). The electrical device 1100 may include a Global Navigation Satellite System (GNSS) device 1118 (or corresponding interface circuitry, as discussed above), such as a Global Positioning System (GPS) device. The GNSS device 1118 may be in communication with a satellite-based system and may determine a geolocation of the electrical device 1100 based on information received from one or more GNSS satellites, as known in the art.

The electrical device 1100 may include other output device(s) 1110 (or corresponding interface circuitry, as discussed above). Examples of the other output device(s) 1110 may include an audio codec, a video codec, a printer, a wired or wireless transmitter for providing information to other devices, or an additional storage device.

The electrical device 1100 may include other input device(s) 1120 (or corresponding interface circuitry, as discussed above). Examples of the other input device(s) 1120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1100 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a display device (e.g., monitor, television), a set-top box, an entertainment control unit, a video game console, a video playback device, a vehicle control unit, a digital camera, a digital video recorder, a wearable electrical device, an appliance, or an embedded computing system (e.g., computing systems that are part of a vehicle, smart home appliance, consumer electronics product or equipment, manufacturing equipment). In some embodiments, the electrical device 1100 may be any other electronic device that processes data. In some embodiments, the electrical device 1100 may comprise multiple discrete physical components. Given the range of devices that the electrical device 1100 can be manifested as in various embodiments, in some embodiments, the electrical device 1100 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for case of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/−10% of a target value (unless otherwise specified). Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “under”, “between”, “adjacent”, “to”, and “on” as used herein may refer to a relative position of one layer or component with respect to other layers or components. For example, one layer “over”, “under”, or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

The term “package” generally refers to a self-contained carrier of one or more dice, where the dice are attached to or embedded in the package substrate, and may be encapsulated for protection, with integrated or wire-bonded interconnects between the dice, along with leads, pins, or bumps located on the external portions of the package substrate. The package may contain a single die, or multiple dice, providing respective functions. The package may be mounted on a printed circuit board for interconnection with other packaged integrated circuits and discrete components, forming a larger circuit.

The term “cored” generally refers to a substrate of an integrated circuit package built upon a board, card, or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core may allow for higher-density package architectures, as the through-vias may have relatively large dimensions and pitch compared to high-density interconnects.

The term “land side” generally refers to the side of the substrate of the integrated circuit package closest to the plane of attachment to a printed circuit board, motherboard, or other package. This is in contrast to the term “die side”, which generally refers to the side of the substrate of the integrated circuit package to which the die or dice are attached.

The terms “dielectric” and “dielectric material” generally refer to any type or number of non-electrically conductive materials. In some cases, dielectric material may be used to make up the structure of a package substrate. For example, dielectric material may be incorporated into an integrated circuit package as layers of laminate film or as a resin molded over integrated circuit dice mounted on the substrate.

The term “metallization” generally refers to metal layers formed on, over, and/or through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and may carry the same or similar meaning.

The term “bump” generally refers to a conductive layer or structure formed on a bond pad, which is typically made of solder or metal and has a round or curved shape, hence the term “bump”.

The term “substrate” generally refers to a planar platform. A substrate may mechanically support and electrically couple one or more IC dies on a single platform, with encapsulation of the one or more IC dies by a moldable dielectric material. A substrate may include bumps or pads as bonding interconnects on one or both sides. For example, one side of the substrate, generally referred to as the “die side”, may include bumps or pads for chip or die bonding. The opposite side of the substrate, generally referred to as the “land side”, may include bumps or pads for bonding the package to a printed circuit board.

The term “assembly” generally refers to a grouping of parts into a single functional unit. For example, certain parts may be permanently bonded together, integrated together, and/or mechanically assembled (e.g., where parts may be removable) into a functional unit.

The terms “coupled” or “connected” means a direct or indirect connection, such as a direct electrical, mechanical, magnetic, or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal.

### EXAMPLES

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a microelectronic assembly, comprising: a first substrate comprising a cavity, wherein the first substrate is oriented on a first plane; and one or more second substrates embedded in the cavity, wherein the one or more second substrates are oriented on one or more second planes, wherein the one or more second planes are substantially orthogonal to the first plane.

Example 2 includes the microelectronic assembly of Example 1, wherein the one or more respective second substrates are oriented vertically in the cavity of the first substrate.

Example 3 includes the microelectronic assembly of any of Examples 1-2, wherein at least one of the second substrates comprises one or more inductors, wherein the one or more inductors are oriented vertically in the cavity of the first substrate.

Example 4 includes the microelectronic assembly of any of Examples 1-3, wherein at least one of the second substrates comprises one or more capacitors, wherein the one or more capacitors are oriented vertically in the cavity of the first substrate.

Example 5 includes the microelectronic assembly of any of Examples 1-4, wherein at least one of the second substrates comprises one or more conductive traces, wherein the one or more conductive traces are oriented vertically in the cavity of the first substrate.

Example 6 includes the microelectronic assembly of any of Examples 1-5, wherein the one or more second substrates comprise a plurality of second substrates, wherein the plurality of second substrates are laminated together.

Example 7 includes the microelectronic assembly of Example 6, wherein the plurality of second substrates include: at least one substrate comprising one or more inductors, wherein the one or more inductors are oriented vertically in the cavity of the first substrate; at least one substrate comprising one or more capacitors, wherein the one or more capacitors are oriented vertically in the cavity of the first substrate; and at least one substrate comprising one or more conductive traces, wherein the one or more conductive traces are oriented vertically in the cavity of the first substrate.

Example 8 includes the microelectronic assembly of any of Examples 1-7, wherein: the cavity extends through the first substrate; and the one or more second substrates extend through the cavity.

Example 9 includes the microelectronic assembly of any of Examples 1-8, wherein a length or a width of the one or more respective second substrates is substantially equivalent to a thickness of the first substrate.

Example 10 includes an electronic device, comprising: a package substrate comprising a cavity; and one or more patch substrates embedded in the cavity, wherein individual patch substrates are oriented vertically in the cavity.

Example 11 includes the electronic device of Example 10, wherein at least one of the patch substrates comprises one or more inductors, wherein the one or more inductors are oriented vertically in the cavity of the package substrate.

Example 12 includes the electronic device of any of Examples 10-11, wherein at least one of the patch substrates comprises one or more capacitors, wherein the one or more capacitors are oriented vertically in the cavity of the package substrate.

Example 13 includes the electronic device of any of Examples 10-12, wherein at least one of the patch substrates comprises one or more conductive traces, wherein the one or more conductive traces are oriented vertically in the cavity of the package substrate.

Example 14 includes the electronic device of any of Examples 10-13, wherein the one or more patch substrates comprise a plurality of patch substrates, wherein the plurality of patch substrates are laminated together.

Example 15 includes the electronic device of Example 14, wherein the plurality of patch substrates include: at least one substrate comprising one or more inductors, wherein the one or more inductors are oriented vertically in the cavity of the package substrate; at least one substrate comprising one or more capacitors, wherein the one or more capacitors are oriented vertically in the cavity of the package substrate; and at least one substrate comprising one or more conductive traces, wherein the one or more conductive traces are oriented vertically in the cavity of the package substrate.

Example 16 includes the electronic device of any of Examples 10-15, wherein: the cavity extends through the package substrate; and the one or more patch substrates extend through the cavity.

Example 17 includes the electronic device of any of Examples 10-16, wherein a length or a width of the one or more respective patch substrates is substantially equivalent to a thickness of the package substrate.

Example 18 includes the electronic device of any of Examples 10-17, further comprising an integrated circuit die coupled to the package substrate, wherein the integrated circuit die comprises processing circuitry, memory circuitry, storage circuitry, or communication circuitry.

Example 19 includes the electronic device of any of Examples 10-18, further comprising: a circuit board; and an integrated circuit coupled to the circuit board, wherein the integrated circuit comprises the package substrate and the one or more patch substrates.

Example 20 includes the electronic device of any of Examples 10-19, wherein the electronic device is a mobile device, a wearable device, a computer, a server, a video playback device, a video game console, a display device, a camera, or an appliance.

Example 21 includes a method, comprising: receiving a first substrate, wherein the first substrate comprises a cavity; receiving a second substrate; and embedding the second substrate in the cavity of the first substrate, wherein the second substrate is oriented vertically in the cavity.

Example 22 includes the method of Example 21, wherein embedding the second substrate in the cavity of the first substrate comprises: rotating the second substrate from a horizontal orientation to a vertical orientation; and embedding the second substrate in the cavity of the first substrate in the vertical orientation.

Example 23 includes the method of any of Examples 21-22, wherein the second substrate comprises: one or more inductors; one or more capacitors; or one or more conductive traces.

1. A microelectronic assembly, comprising:
a first substrate comprising a cavity, wherein the first substrate is oriented on a first plane; and
one or more second substrates embedded in the cavity, wherein the one or more second substrates are oriented on one or more second planes, wherein the one or more second planes are substantially orthogonal to the first plane.

2. The microelectronic assembly of claim 1, wherein the one or more respective second substrates are oriented vertically in the cavity of the first substrate.

3. The microelectronic assembly of claim 1, wherein at least one of the second substrates comprises one or more inductors, wherein the one or more inductors are oriented vertically in the cavity of the first substrate.

4. The microelectronic assembly of claim 1, wherein at least one of the second substrates comprises one or more capacitors, wherein the one or more capacitors are oriented vertically in the cavity of the first substrate.

5. The microelectronic assembly of claim 1, wherein at least one of the second substrates comprises one or more conductive traces, wherein the one or more conductive traces are oriented vertically in the cavity of the first substrate.

6. The microelectronic assembly of claim 1, wherein the one or more second substrates comprise a plurality of second substrates, wherein the plurality of second substrates are laminated together.

7. The microelectronic assembly of claim 6, wherein the plurality of second substrates include:
at least one substrate comprising one or more inductors, wherein the one or more inductors are oriented vertically in the cavity of the first substrate;
at least one substrate comprising one or more capacitors, wherein the one or more capacitors are oriented vertically in the cavity of the first substrate; and
at least one substrate comprising one or more conductive traces, wherein the one or more conductive traces are oriented vertically in the cavity of the first substrate.

8. The microelectronic assembly of claim 1, wherein:
the cavity extends through the first substrate; and
the one or more second substrates extend through the cavity.

9. The microelectronic assembly of claim 1, wherein a length or a width of the one or more respective second substrates is substantially equivalent to a thickness of the first substrate.

10. An electronic device, comprising:
a package substrate comprising a cavity; and
one or more patch substrates embedded in the cavity, wherein individual patch substrates are oriented vertically in the cavity.

11. The electronic device of claim 10, wherein at least one of the patch substrates comprises one or more inductors, wherein the one or more inductors are oriented vertically in the cavity of the package substrate.

12. The electronic device of claim 10, wherein at least one of the patch substrates comprises one or more capacitors, wherein the one or more capacitors are oriented vertically in the cavity of the package substrate.

13. The electronic device of claim 10, wherein at least one of the patch substrates comprises one or more conductive traces, wherein the one or more conductive traces are oriented vertically in the cavity of the package substrate.

14. The electronic device of claim 10, wherein the one or more patch substrates comprise a plurality of patch substrates, wherein the plurality of patch substrates are laminated together.

15. The electronic device of claim 14, wherein the plurality of patch substrates include:
at least one substrate comprising one or more inductors, wherein the one or more inductors are oriented vertically in the cavity of the package substrate;
at least one substrate comprising one or more capacitors, wherein the one or more capacitors are oriented vertically in the cavity of the package substrate; and
at least one substrate comprising one or more conductive traces, wherein the one or more conductive traces are oriented vertically in the cavity of the package substrate.

16. The electronic device of claim 10, further comprising an integrated circuit die coupled to the package substrate, wherein the integrated circuit die comprises processing circuitry, memory circuitry, storage circuitry, or communication circuitry.

17. The electronic device of claim 10, wherein the electronic device is a mobile device, a wearable device, a computer, a server, a video playback device, a video game console, a display device, a camera, or an appliance.

18. A method, comprising:
receiving a first substrate, wherein the first substrate comprises a cavity;
receiving a second substrate; and
embedding the second substrate in the cavity of the first substrate, wherein the second substrate is oriented vertically in the cavity.

19. The method of claim 18, wherein embedding the second substrate in the cavity of the first substrate comprises:
rotating the second substrate from a horizontal orientation to a vertical orientation; and
embedding the second substrate in the cavity of the first substrate in the vertical orientation.

20. The method of claim 18, wherein the second substrate comprises:
one or more inductors;
one or more capacitors; or
one or more conductive traces.
